(19) United States
(12) Patent Application Publication
(10) Pub. No.: US 2026/0235963 A1
(43) Pub. Date: Aug. 13, 2026

(54) EXPOSURE DEVICE AND EXPOSURE METHOD

(71) Applicant: Fujikura Ltd., Tokyo (JP)

(72) Inventor: Takahiro Nambara, Tokyo (JP)

(73) Assignee: Fujikura Ltd., Tokyo (JP)

(21) Appl. No.: 19/154,072

(22) PCT Filed: Dec. 14, 2023
(86) PCT No.: PCT/JP2023/044764

§ 371 Date: Aug. 6, 2025

Related U.S. Application Data
(60) Provisional application No. 63/443,850, filed on Feb. 7, 2023.

(51) Int. Cl. G03F 7/00; G02B 26/10

(52) U.S. Cl. CPC G03F 7/70375; G02B 26/105; G03F 7/704

(57) ABSTRACT

An exposure device includes: an exposure lens system having positive power; and a scanning optical system configured to switch a direction of a principal ray of a light beam entering the exposure lens system. 0<D<2×F1, where D is a distance from a principal point of the exposure lens system to either of: an intersection position of a light beam group entering the exposure lens system, or among intersection positions of a light beam group entering the exposure lens system, an intersection position closest to the exposure lens system, and F1 is a front-side focal distance of the exposure lens system.

### TECHNICAL FIELD

The present invention relates to an exposure device. The present invention further relates to an exposure method which carries out two-photon exposure by using the exposure device.

### BACKGROUND

Such an exposure device is widely used that condenses light into an inside of a sample so as to cause two-photon absorption at a location near a light-converged point. For example, Patent Literature 1 discloses a technique for carrying out optical shaping by using such an exposure device.

### PATENT LITERATURE

### Patent Literature 1

Japanese Patent Application Publication, Tokukai, No. 2001-158050

As disclosed also in Patent Literature 1, a conventional exposure device is configured to allow light to enter a sample T as shown in FIG. 13. A light beam B1 which perpendicularly enters a principal plane of an exposure lens L forms a light-converged area A1 perpendicularly to a principal plane of an exposure lens system 11, the light-converged area A1 being an area in which a given exposure phenomenon (e.g., two-photon absorption) occurs. Therefore, a shape of the area where the given exposure phenomenon occurs can be easily made more closely resemble a desired shape. Meanwhile, a light beam B2 which obliquely enters the principal plane of the exposure lens L forms a light-converged area A2 in an inclined manner, the light-converged area A2 being an area in which the given exposure phenomenon occurs. Therefore, the shape of the area where the given exposure phenomenon occurs cannot be made more closely resemble the desired shape. That is, with increasing distance from an optical axis of the exposure lens L, it becomes more difficult to make the shape of the area where the given exposure phenomenon occurs more closely resemble the desired shape.

The reason why the light beam B2 obliquely entering the principal plane of the exposure lens L forms the light-converged area A2, in which the given exposure phenomenon occurs, such that the light-converged area A2 is inclined is as follows. That is, the exposure lens L itself functions as an entrance pupil, and a principal ray of the light beam B2 obliquely entering the exposure lens L passes through a principal point of the exposure lens L (i.e., passes through the exposure lens L without being refracted).

### SUMMARY

One or more embodiments of the present invention provide an exposure device which can make a shape of an area where a given exposure phenomenon occurs more closely resemble a desired shape even at a location distant from an optical axis of an exposure lens system.

An exposure device in accordance with an aspect of the present invention includes: an exposure lens system which has positive power; and a scanning optical system which is configured to switch, from one to another, a direction of a principal ray of a light beam entering the exposure lens system, a distance D satisfying 0<D<2×F1, where the distance D is a distance from (a) a single intersection position of a light beam group entering the exposure lens system or, among a plurality of intersection positions of the light beam group, an intersection position closest to the exposure lens system to (b) a principal point of the exposure lens system and F1 denotes a front-side focal distance of the exposure lens system.

In accordance with an aspect of the present invention, it is possible to make a shape of an area where a given exposure phenomenon occurs more closely resemble a desired shape even at a location distant from an optical axis of an exposure lens system.

### BRIEF DESCRIPTION OF THE DRAWINGS

FIG. 1 is a plan view illustrating a configuration of an exposure device in accordance with first embodiments of the present invention, where D=F1 is satisfied.

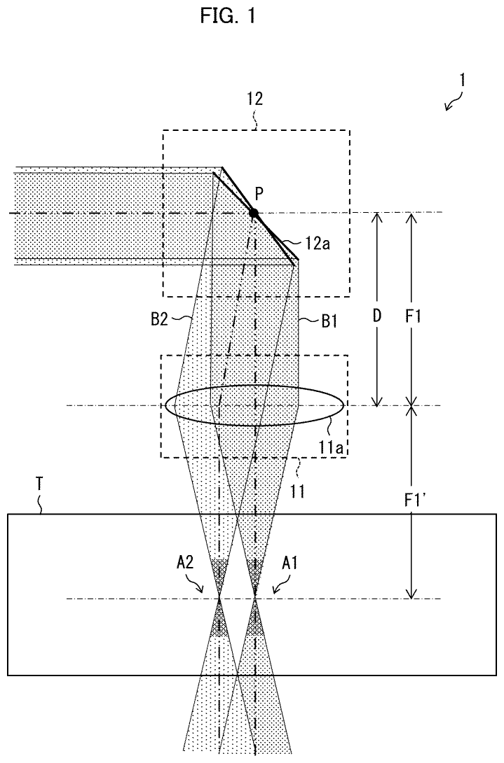

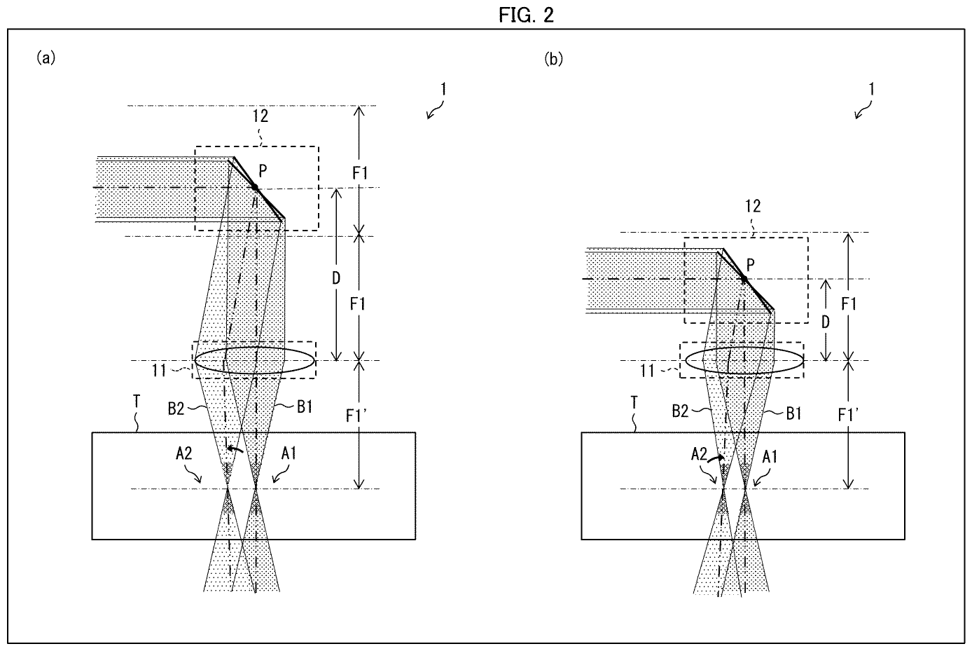

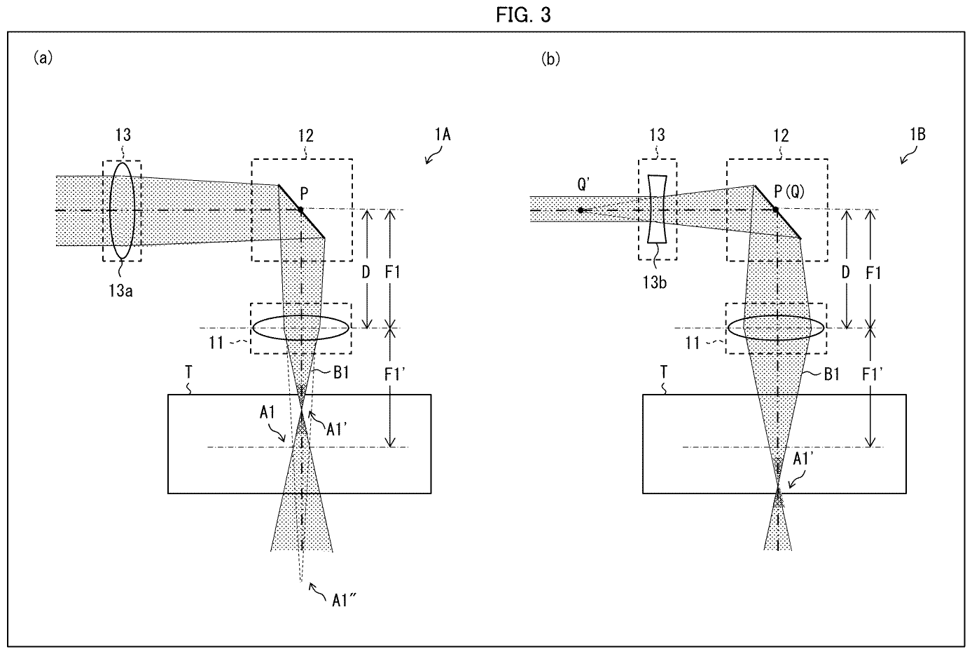

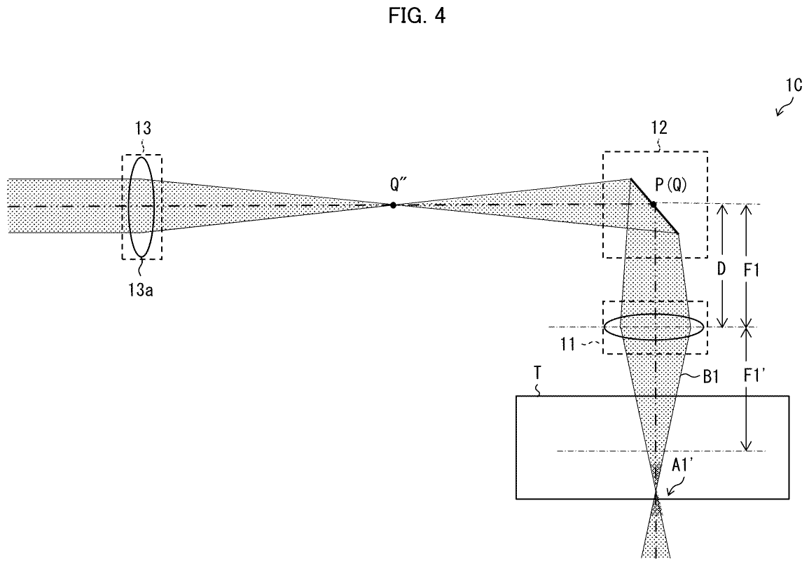

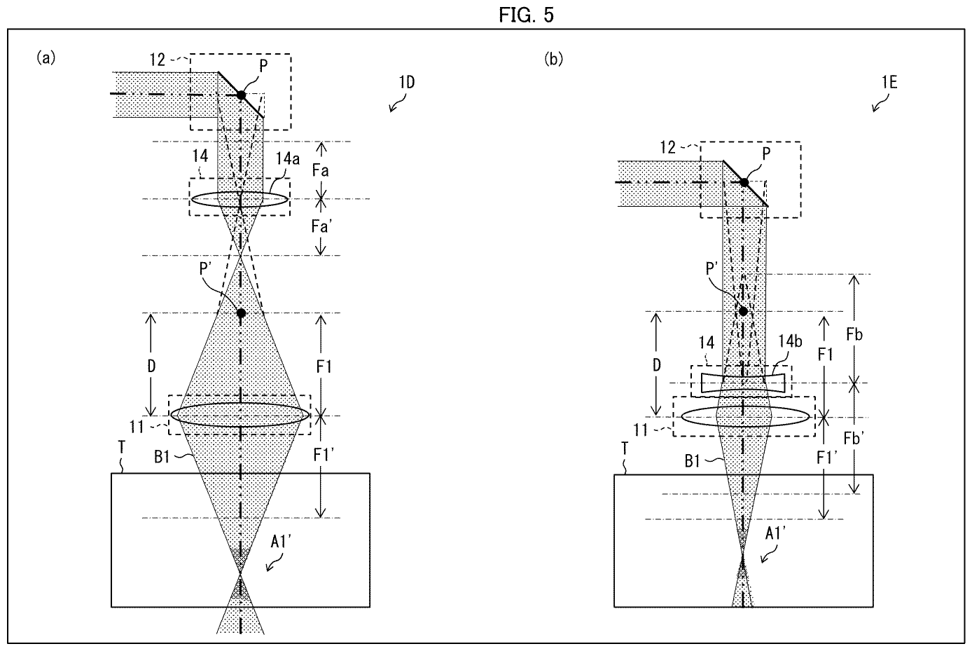

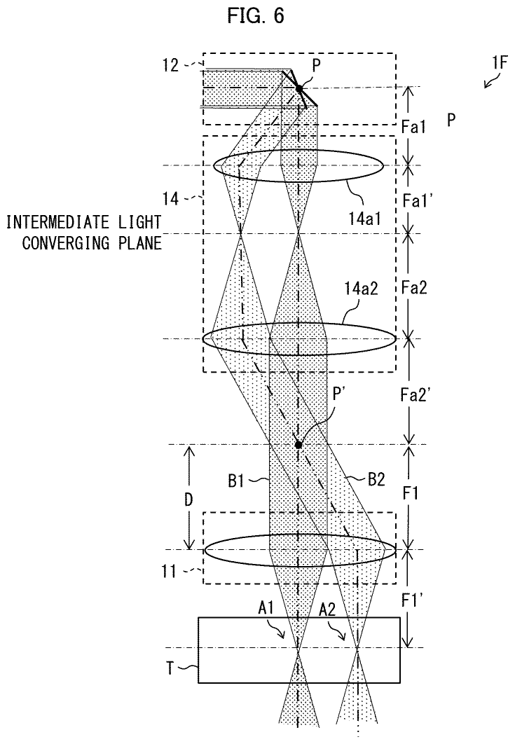

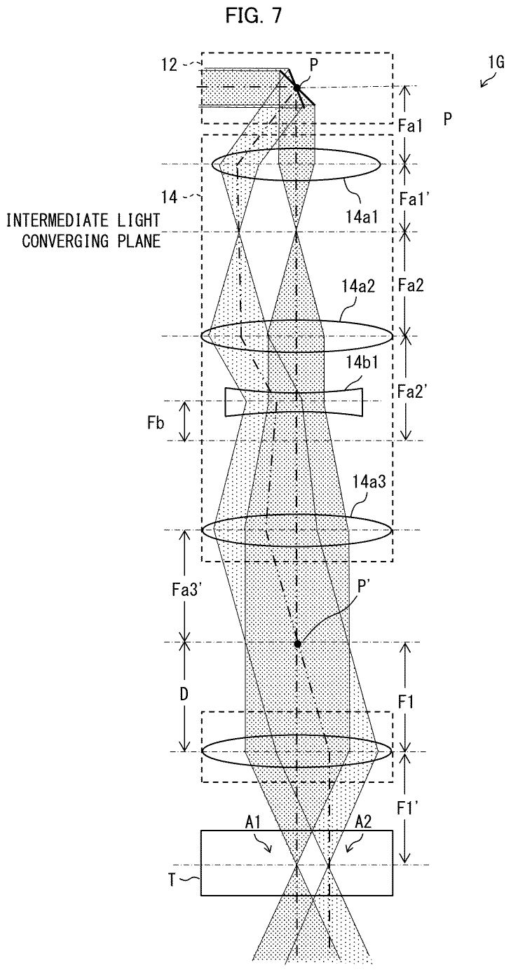

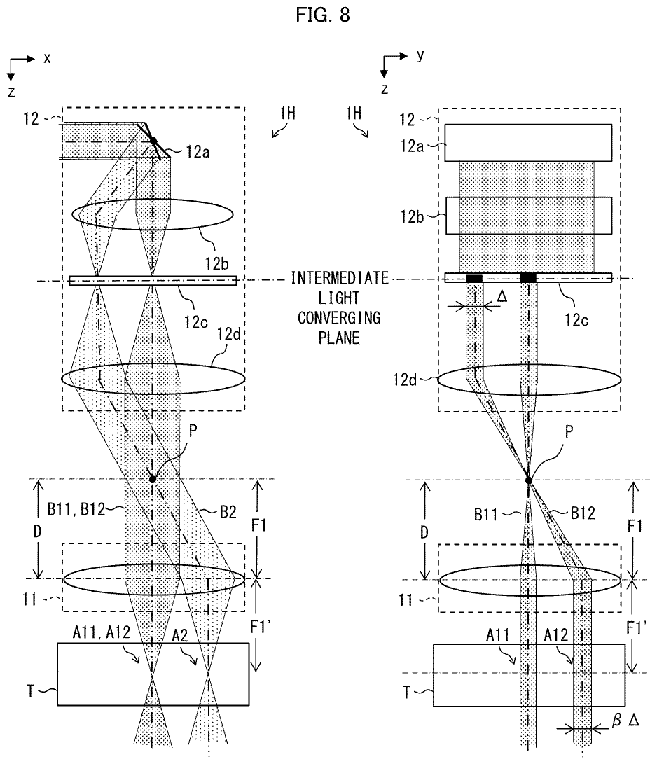

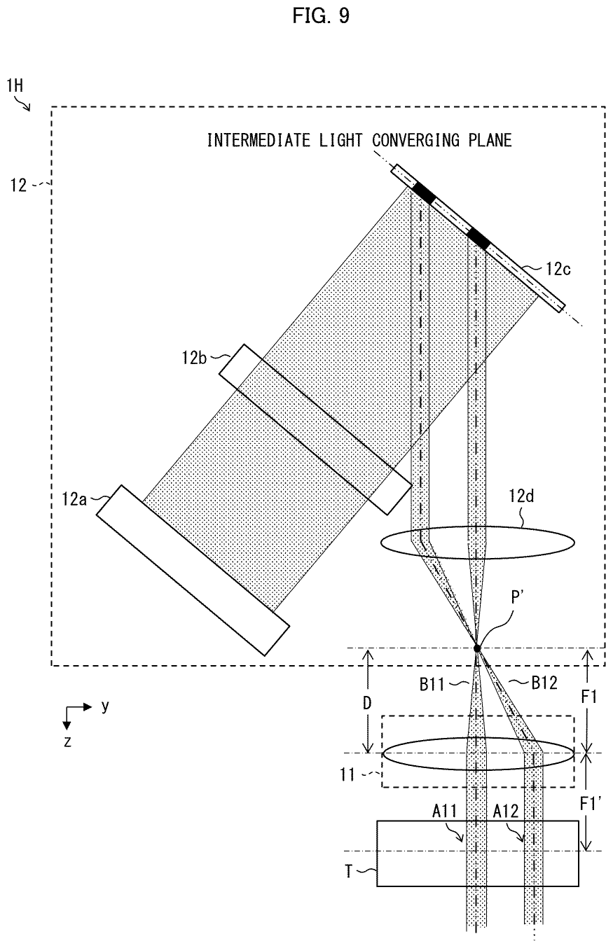

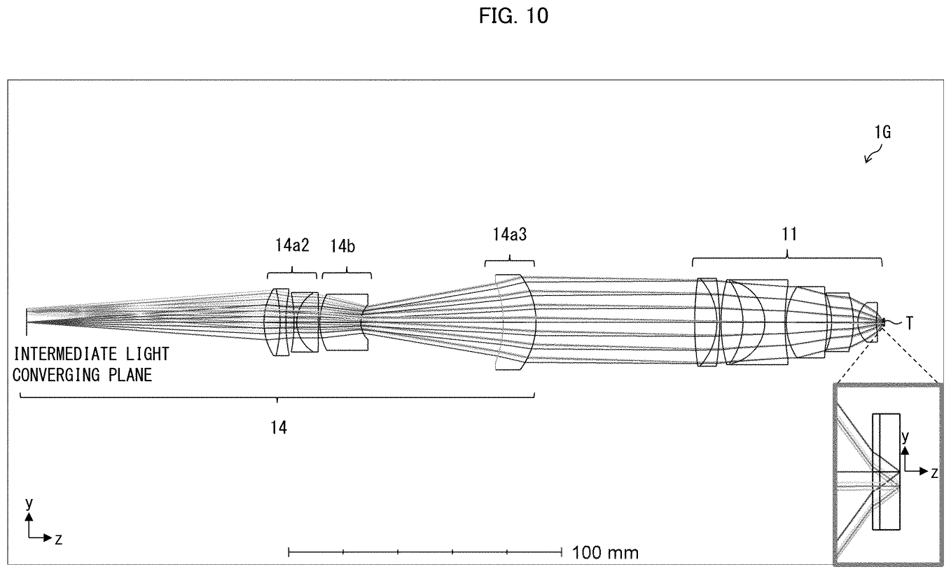

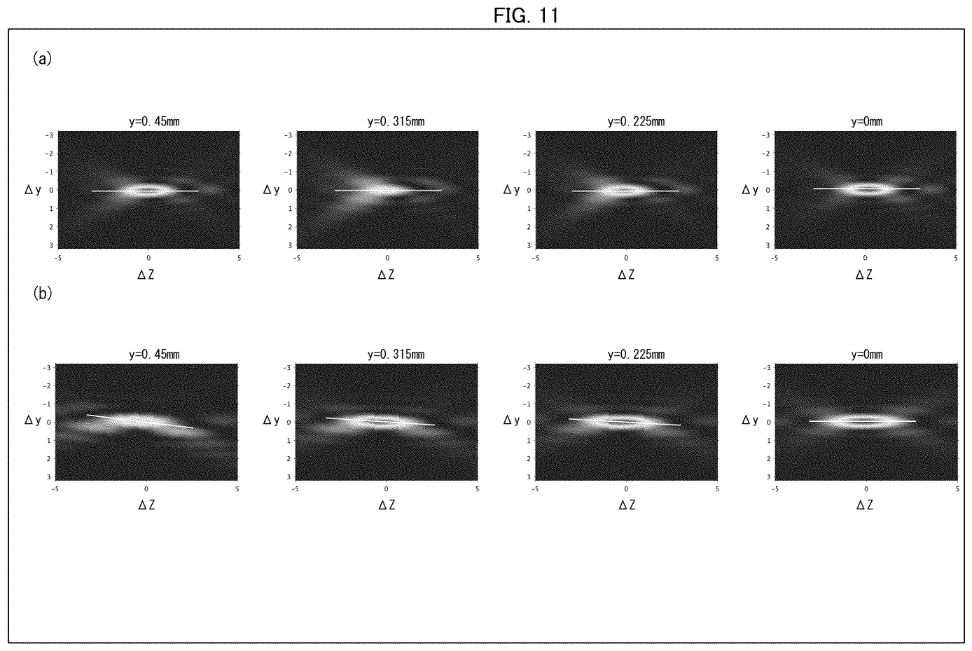

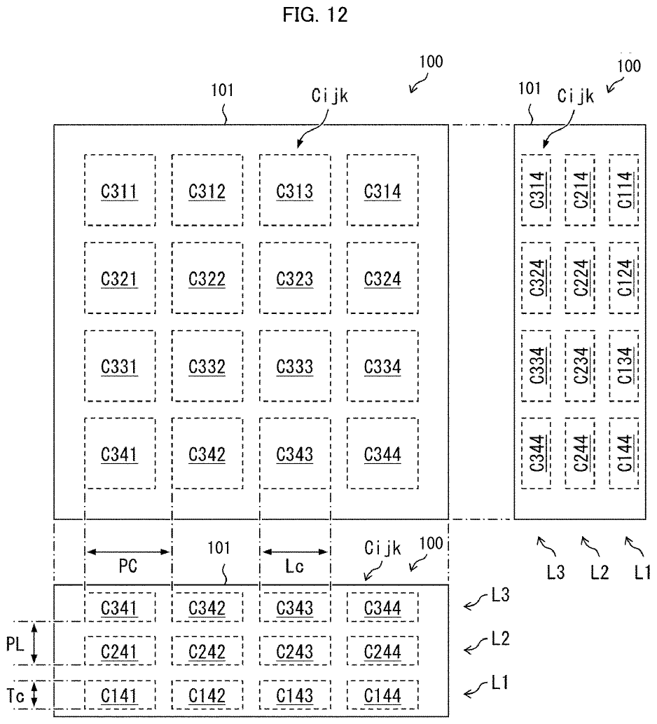

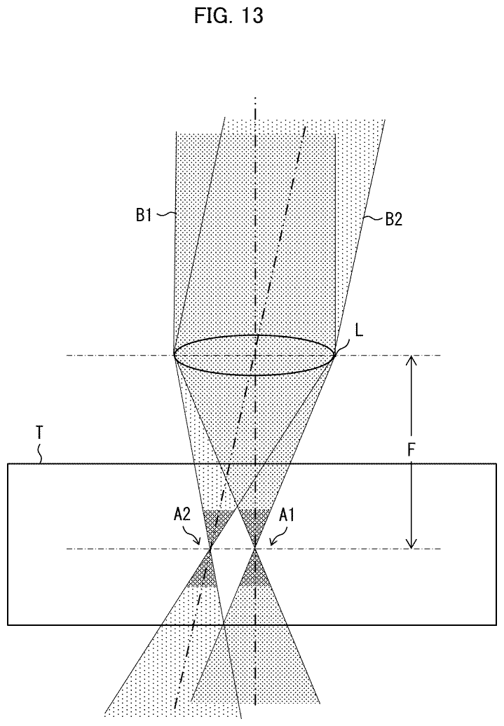

(a) of FIG. 2 is a plan view illustrating a configuration of the exposure device shown in FIG. 1, where F1<D<2×F2 is satisfied. (b) of FIG. 2 is a plan view illustrating a configuration of the exposure device shown in FIG. 1, where 0<D<F1 is satisfied.

(a) of FIG. 3 is a plan view illustrating a configuration of an exposure device in accordance with second embodiments of the present invention, the exposure device including a front optical system having positive power. (b) of FIG. 3 is a plan view illustrating a configuration of an exposure device in accordance with the second embodiments of the present invention, the exposure device including a front optical system having negative power.

FIG. 4 is a plan view illustrating a configuration of the exposure device in accordance with the second embodiments of the present invention, the exposure device including the front optical system having positive power.

(a) of FIG. 5 is a plan view illustrating a configuration of an exposure device in accordance with third embodiments of the present invention, the exposure device including an intermediate optical system having positive power. (b) of FIG. 5 is a plan view illustrating a configuration of an exposure device in accordance with the third embodiments of the present invention, the exposure device including an intermediate optical system having negative power.

FIG. 6 is a plan view illustrating a configuration of an exposure device in accordance with fourth embodiments of the present invention, the exposure device including an intermediate optical system which is a Keplerian afocal system.

FIG. 7 is a plan view illustrating a configuration of an exposure device in accordance with the fourth embodiments of the present invention, the exposure device including an intermediate optical system made of a combination of a Keplerian afocal system and a Galilean afocal system.

FIG. 8 is a plan view of an exposure device, in accordance with fifth embodiments of the present invention, including a transmissive optical switch, as viewed in a y-axis direction and an x-axis direction.

FIG. 9 is a plan view of an exposure device, in accordance with the fifth embodiments of the present invention, including a reflective optical switch, as viewed in the x-axis direction.

FIG. 10 is a plan view illustrating a part of a configuration of an exposure device in accordance with one or more embodiments of the present invention.

(a) of FIG. 11 shows graphs showing distributions of intensities of light obtained when light-converged areas were formed at respective locations in a sample by using the exposure device shown in FIG. 11. (b) of FIG. 11 shows graphs showing distributions of intensities of light obtained when light-converged areas were formed at respective locations in a sample by using a conventional exposure device.

FIG. 12 is a three-side view illustrating a configuration of an optical computing device produced by a production method in accordance with one or more embodiments of the present invention.

FIG. 13 is a plan view illustrating a configuration of a conventional exposure device.

### DETAILED DESCRIPTION

### First Embodiments

The following description will discuss, with reference to FIGS. 1 and 2, first embodiments of the present invention. Note that the present embodiments serve as a base of the later-described embodiments.

### Configuration of Exposure Device

The following will describe, with reference to FIG. 1, a configuration of an exposure device 1 in accordance with one or more embodiments. FIG. 1 is a plan view illustrating the configuration of the exposure device 1.

The exposure device 1 is a device for carrying out two-photon exposure, and includes an exposure lens system 11 and a scanning optical system 12 as shown in FIG. 1.

The exposure lens system 11 is a lens system having positive power. The exposure lens system 11 is constituted by at least one lens. In a case where the exposure lens system 11 is constituted by two or more lenses, the exposure lens system 11 may have positive power as a whole and may include a negative lens. In an example shown in FIG. 1, a lens system constituted by a single positive lens 11a is illustrated as the exposure lens system 11.

The scanning optical system 12 is a configuration for switching, from one to another, a direction of a principal ray of a light beam entering the exposure lens system 11. In the example shown in FIG. 1, an optical system constituted by a single mirror 12a is illustrated as the scanning optical system 12. The mirror 12a is configured such that an orientation of a reflection surface of the mirror 12a is freely controllable while having a fixed point which is a center of the reflection surface. When the orientation of the mirror 12a changes, an area (hereinafter, also referred to as an “angle of view”) of a sample T viewed from the scanning optical system 12 through the exposure lens system 11 changes.

In the scanning optical system 12 shown in FIG. 1, the exposure lens system 11 does not function as an entrance pupil but the scanning optical system 12 functions as the entrance pupil. Thus, an intersection position P of a light beam group (a group of light beams corresponding to a respective angle of view) entering the exposure lens system 11 is formed on the center of the reflection surface of the mirror 12a, rather than on a principal point of the exposure lens system 11. Note that the above-described intersection position P is represented by, for example, a fixed point (fixpoint) of principal rays of the respective light beams included in the above-described light beam group. As the mirror 12a, it is possible to use a Micro Electro Mechanical System (MEMS) mirror, a galvano mirror, or a polygon mirror.

The light beam B1 and B2 condensed by the exposure lens system 11 respectively form light-converged areas A1 and A2 in an inside of the sample T. Here, each of the light-converged areas A1 and A2 refers to an area of a corresponding one of the light beams B1 and B2 where an energy density exceeds a prescribed threshold. In the exposure device 1, it is possible to form the light-converged areas A1 and A2 at desired locations in the sample T by controlling the scanning optical system 12. In one or more embodiments, areas where two-photon exposure (two-photon absorption) occurs are considered as the light-converged areas A1 and A2. Thus, in the exposure device 1, it is possible to cause two-photon exposure at a desired location in the sample T by controlling the scanning optical system 12.

The exposure device 1 has the following characteristic. That is, a distance D from the intersection position P to the principal point of the exposure lens system 11 is equal to a front-side focal distance F1 of the exposure lens system 11, that is, a condition of telecentricity is satisfied. Thus, not only the light beam B1 perpendicularly entering the principal plane of the exposure lens system 11 but also the light beam B2 obliquely entering the principal plane of the exposure lens system 11 perpendicularly exits from the exposure lens system 11. Therefore, not only the light-converged area A1 of the light beam B1 perpendicularly entering the exposure lens system 11 but also the light-converged area A2 of the light beam B2 obliquely entering the exposure lens system 11 is orthogonal to the principal plane of the exposure lens system 11. Consequently, even at a location distant from an optical axis of the exposure lens system 11, it is possible to make a shape of an area where two-photon exposure occurs into a desired shape.

Provided that the distance D from the intersection position P to the principal point of the exposure lens system 11 satisfies 0<D<2×F1, it is possible to attain an effect equivalent to the above-described effect.
(a) of FIG. 2 is a plan view of the exposure lens 1, where the distance D from the intersection position P to the principal point of the exposure lens system 11 satisfies F1<D <2×F1. In this case, the light-converged area A2 of the light beam B2 whose principal ray obliquely enters the principal plane of the exposure lens system 11 is slightly inclined in a counterclockwise direction. However, the inclination is smaller than that occurring for a conventional exposure lens (corresponding to D=0). Therefore, distortion of a shape of an area where two-photon exposure occurs, which distortion can occur at a location distant from the optical axis of the exposure lens system 11, can be suppressed or reduced more, as compared to a case where a conventional exposure device is used.
(b) of FIG. 2 is a plan view of the exposure lens 1, where the distance D from the intersection position P to the principal point of the exposure lens system 11 satisfies 0<D<F1. In this case, the light-converged area A2 of the light beam B2 whose principal ray obliquely enters the exposure lens system 11 is slightly inclined in a clockwise direction. However, the inclination is smaller than that occurring for the conventional exposure lens (corresponding to D=0). Therefore, distortion of a shape of an area where two-photon exposure occurs, which distortion can occur at a location distant from the optical axis of the exposure lens system 11, can be suppressed or reduced more, as compared to a case where the conventional exposure device is used.

In a case where the configuration in which the distance D satisfies 0<D≤F1 (the configuration shown in FIG. 1 and (b) of FIG. 2) and the configuration in which the distance D satisfies F1<D<2×F2 (the configuration shown in (a) of FIG. 2), the former configuration can reduce a distance between the exposure lens system 11 and the scanning optical system 12 more. Therefore, the former configuration is more advantageous in terms of a capability of reducing the size of the device and a capability of reducing an effect of disturbance on exposure resolution.

When the configuration in which the distance D satisfies 0<D<F1 (the configuration shown (b) of FIG. 2) and the configuration in which the distance D satisfies F1≤D<2×F2 (the configuration shown in FIG. 1 and (a) of FIG. 2), the latter configuration can minimize an amount of change of an orientation of the mirror 12a which is necessary to obtain a certain angle of view more. Therefore, the latter configuration is more advantageous in terms of a capability of increasing a scanning speed. Further, the latter configuration can make, by a certain amount of change of the orientation of the mirror 12a, a principal ray of a light beam entering the exposure lens system 11 more separated from the optical axis of the exposure lens system 11. Therefore, the latter configuration is more advantageous in terms of a capability of easily correcting distortion.

### Second Embodiments

The following description will discuss, with reference to FIGS. 3 and 4, second embodiments of the present invention. Note that the present embodiments are obtained by adding a front optical system 13 to the exposure device 1 in accordance with the first embodiments. The “front optical system” herein refers to an optical system disposed on a front side of the scanning optical system 12.

Note that the expression “front” herein refers to an upstream side in a traveling direction of light which enters the scanning optical system 12 so that its traveling direction is changed by the scanning optical system 12 and then enters the exposure lens system 11 so as to be condensed by the exposure lens system 11. Similarly, the expression “rear” herein refers to a downstream side in a traveling direction of light which enters the scanning optical system 12 so that its traveling direction is changed by the scanning optical system 12 and then enters the exposure lens system 11 so as to be condensed by the exposure lens system 11.

### Configuration of Exposure Device

The following will describe, with reference to FIG. 3, configurations of exposure devices 1A and 1B of one or more embodiments.
(a) of FIG. 3 is a plan view of the exposure device 1A. As shown in (a) of FIG. 3, the exposure device 1A is obtained by adding, to the exposure device 1 in accordance with the first embodiments, a front optical system 13 having positive power such that the front optical system 13 is disposed on a front side of a scanning optical system 12. In an example shown in (a) of FIG. 3, an optical system constituted by a positive lens 13a is illustrated as the front optical system 13. The front optical system 13 is disposed such that a light-converged area A1″ (a light-converged area obtained in a case where an exposure lens system 11 is not present) obtained only with the front optical system 13 is located on a rear side of a light-converged area A1 (a light-converged area obtained in a case where the front optical system 13 is not present) obtained only with the exposure lens system 11.

Also in the exposure device 1A, a distance D from the above-described intersection position P to a principal point of the exposure lens system 11 is equal to a front-side focal distance F1 of the exposure lens system 11 (a condition of telecentricity is satisfied). Therefore, similarly to the exposure device 1 in accordance with the first embodiments, the exposure device 1A can suppress or reduce distortion of a shape of an area where two-photon exposure occurs, which distortion can occur at a location distant from an optical axis of the exposure lens system 11.

Further, in the exposure device 1A, due to an effect of the front optical system 13, a light beam B1 entering the exposure lens system 11 from the scanning optical system 12 is a converging light beam. Thus, a distance from the principal point of the exposure lens system 11 to a light-converged area A1′ is shorter than a rear-side focal distance F1′ of the exposure lens system 11. Note that the front optical system 13 also functions as a focus lens. That is, disposing the front optical system 13 so as to be closer to the scanning optical system 12 can make the light-converged area A1′ more distant from the exposure lens system 11. Meanwhile, disposing the front optical system 13 so as to be more distant from the scanning optical system 12 can make the light-converged area A1′ closer to the exposure lens system 11.
(b) of FIG. 3 is a plan view of the exposure device 1B. As shown in (b) of FIG. 3, the exposure device 1B is obtained by adding, to the exposure device 1 in accordance with the first embodiments, a front optical system 13 having negative power such that the front optical system 13 is disposed on a front side of a scanning optical system 12. In an example shown in (b) of FIG. 3, an optical system constituted by a negative lens 13b is illustrated as the front optical system 13. The front optical system 13 is disposed such that a front side focal point Q′ of the front optical system 13 is located on a front side of a front side focal point Q of the exposure lens system 11 (in the illustrated configuration, the front side focal point Q′ is equal to an intersection position P).

Also in the exposure device 1B, a distance D from the above-described intersection position P to a principal point of the exposure lens system 11 is equal to a front-side focal distance F1 of the exposure lens system 11 (a condition of telecentricity is satisfied). Therefore, similarly to the exposure device 1 in accordance with the first embodiments, the exposure device 1B can suppress or reduce distortion of a shape of an area where two-photon exposure occurs more than the conventional exposure device does, which distortion can occur at a location distant from an optical axis of the exposure lens system 11.

Further, in the exposure device 1B, due to an effect of the front optical system 13, a light beam B1 entering the exposure lens system 11 from the scanning optical system 12 is a diverging light beam. Thus, a distance from the principal point of the exposure lens system 11 to a light-converged area A1′ is longer than a rear-side focal distance F1′ of the exposure lens system 11. Note that front optical system 13 also functions as a focus lens. That is, disposing the front optical system 13 so as to be closer to the scanning optical system 12 can make the light-converged area A1′ closer to the exposure lens system 11. Meanwhile, disposing the front optical system 13 so as to be more distant from the scanning optical system 12 can make the light-converged area A1′ more distant from the exposure lens system 11.

### Variation of Exposure Device

The following will describe, with reference to FIG. 4, a variation (hereinafter, referred to as an “exposure device 1C”) of the above-described exposure device 1A. FIG. 4 is a plan view illustrating a configuration of the exposure device 1C.

As shown in FIG. 4, the exposure device 1C is obtained by modifying the above-described exposure device 1A as follows. That is, the front optical system 13 is disposed such that a rear side focal point Q″ of the front optical system 13 is located on a front side of a front optical system Q of the exposure lens system 11 (in the illustrated configuration, the rear side focal point Q″ is equal to an intersection position P).

Also in the exposure device 1C, a distance D from the above-described intersection position P to a principal point of the exposure lens system 11 is equal to a front-side focal distance F1 of the exposure lens system 11 (a condition of telecentricity is satisfied). Therefore, similarly to the exposure device 1 in accordance with the first embodiments, the exposure device 1C can suppress or reduce distortion of a shape of an area where two-photon exposure occurs more than the conventional exposure device does, which distortion can occur at a location distant from an optical axis of the exposure lens system 11.

Further, in the exposure device 1C, due to an effect of the front optical system 13, a light beam B1 entering the exposure lens system 11 from the scanning optical system 12 is a diverging light beam. Thus, a distance from the principal point of the exposure lens system 11 to a light-converged area A1′ is longer than a rear-side focal distance F1′ of the exposure lens system 11. Note that front optical system 13 also functions as a focus lens. That is, disposing the front optical system 13 so as to be closer to the scanning optical system 12 can make the light-converged area A1′ closer to the exposure lens system 11. Meanwhile, disposing the front optical system 13 so as to be more distant from the scanning optical system 12 can make the light-converged area A1′ more distant from the exposure lens system 11.

Supplementary Remark

Similarly to the exposure device 1 in accordance with the first embodiments, the exposure devices 1A, 1B, and 1C in accordance with one or more embodiments may be configured such that the distance D from the intersection position P to the principal point of the exposure lens system 11 satisfies 0<D<2×F1 and is not limited to D=F1.

### Third Embodiments

The following description will discuss, with reference to FIG. 5, third embodiments of the present invention. Note that the present embodiments are obtained by adding an intermediate optical system 14 to the exposure device 1 in accordance with the first embodiments. The “intermediate optical system” herein refers to an optical system disposed at a location which is between a scanning optical system 12 and an exposure lens system 11, that is, at a location which is on a rear side of the scanning optical system 12 and on a front side of the exposure lens system 11.

### Configuration of Exposure Device

The following will describe, with reference to (a) of FIG. 5, a configuration of an exposure device 1D of one or more embodiments. (a) of FIG. 5 is a plan view of the exposure device 1D.

As shown in (a) of FIG. 5, the exposure device ID is obtained by adding, to the exposure device 1 in accordance with the first embodiments, an intermediate optical system 14 having positive power such that the intermediate optical system 14 is disposed at a location between a scanning optical system 12 and an exposure lens system 11. In an example shown in (a) of FIG. 5, an optical system constituted by a positive lens 14a is illustrated as the intermediate optical system 14.

In the exposure device 1D, at a conjugate position of the above-described intersection position P with respect to the intermediate optical system 14, a new intersection position P′ of a light beam group entering the exposure lens system 11 is formed. In a case where the intermediate optical system 14 has positive power, the conjugate position of the above-described intersection position P is located on a rear side of the intermediate optical system 14. Therefore, the new intersection position P′ is also formed at a location on the rear side of the intermediate optical system 14. The location of the intermediate optical system 14 is defined so that a distance D from the new intersection position P′ to a principal point of the exposure lens system 11 is equal to a front-side focal distance F1 of the exposure lens system 11.

In the exposure device 1D, a distance D from the intersection position P′ to a principal point of the exposure lens system 11 is equal to the front-side focal distance F1 of the exposure lens system 11 (a condition of telecentricity is satisfied). Therefore, similarly to the exposure device 1 in accordance with the first embodiments, the exposure device 1D can suppress or reduce distortion of a shape of an area where two-photon exposure occurs more than the conventional exposure device does, which distortion can occur at a location distant from an optical axis of the exposure lens system 11.

In the exposure device 1D, due to an effect of the intermediate optical system 14, a light beam B1 entering the exposure lens system 11 is a diverging light beam. Thus, a distance from the principal point of the exposure lens system 11 to a light-converged area A1′ is longer than a rear-side focal distance F1′ of the exposure lens system 11. Note that the intermediate optical system 14 also functions as a focus lens. That is, disposing the intermediate optical system 14 so as to be closer to the exposure lens system 11 can make the light-converged area A1′ closer to the exposure lens system 11. Meanwhile, disposing the intermediate optical system 14 so as to be more distant from the exposure lens system 11 can make the light-converged area A1′ more distant from the exposure lens system 11.

The following will describe, with reference to (b) of FIG. 5, a configuration of an exposure device 1E of one or more embodiments. (b) of FIG. 5 is a plan view of the exposure device 1E.

As shown in (b) of FIG. 5, the exposure device 1E is obtained by adding, to the exposure device 1 in accordance with the first embodiments, an intermediate optical system 14 having negative power such that the intermediate optical system 14 is disposed at a location between a scanning optical system 12 and an exposure lens system 11. In an example shown in (b) of FIG. 5, an optical system constituted by a negative lens 14b is illustrated as the intermediate optical system 14.

In the exposure device 1E, at a conjugate position of the above-described intersection position P with respect to the intermediate optical system 14, a new intersection position P′ of a light beam group entering the exposure lens system 11 is formed. In a case where the intermediate optical system 14 has negative power, the conjugate position of the above-described intersection position P is located on a front side of the intermediate optical system 14. Therefore, the new intersection position P′ is also formed at a location on the front side of the intermediate optical system 14. The location of the intermediate optical system 14 is defined so that a distance D from the new intersection position P′ to a principal point of the exposure lens system 11 is equal to a front-side focal distance F1 of the exposure lens system 11.

In the exposure device 1E, a distance D from the intersection position P′ to the principal point of the exposure lens system 11 is equal to the front-side focal distance F1 of the exposure lens system 11 (a condition of telecentricity is satisfied). Therefore, similarly to the exposure device 1 in accordance with the first embodiments, the exposure device 1E can suppress or reduce distortion of a shape of an area where two-photon exposure occurs more than the conventional exposure device does, which distortion can occur at a location distant from an optical axis of the exposure lens system 11.

In the exposure device 1E, due to an effect of the intermediate optical system 14, a light beam B1 entering the exposure lens system 11 is a diverging light beam. Thus, a distance from the principal point of the exposure lens system 11 to a light-converged area A1′ is longer than a rear-side focal distance F1′ of the exposure lens system 11. Note that the intermediate optical system 14 also functions as a focus lens. That is, disposing the intermediate optical system 14 so as to be closer to the exposure lens system 11 can make the light-converged area A1′ closer to the exposure lens system 11. Meanwhile, disposing the intermediate optical system 14 so as to be more distant from the exposure lens system 11 can make the light-converged area A1′ more distant from the exposure lens system 11.

### Supplementary Remark

Similarly to the exposure device 1 in accordance with the first embodiments, the exposure devices 1D and 1E in accordance with the present embodiments may be configured such that the distance D from the intersection position P′ to the principal point of the exposure lens system 11 satisfies 0<D<2×F1 and is not limited to D=F1.

Further, similarly to the exposure devices 1A, 1B, and 1C in accordance with the second embodiments, the exposure devices 1D and 1E in accordance with one or more embodiments may also be configured such that a front optical system 13 is disposed on a front side of the scanning optical system 12.

### Fourth Embodiments

The following description will discuss, with reference to FIGS. 6 and 7, fourth embodiments of the present invention. Note that, similarly to the third embodiments, the present embodiments are obtained by adding an intermediate optical system 14 to the exposure device 1 in accordance with the first embodiments. Note, however, that the intermediate optical system 14 of the fourth embodiments differs from that of the third embodiments, which constitutes an afocal system.

### Configuration of Exposure Device

The following will describe, with reference to FIG. 6, a configuration of an exposure device 1F of one or more embodiments. (b) of FIG. 6 is a plan view of the exposure device 1F.

As shown in FIG. 6, the exposure device 1F is obtained by adding, to the exposure device 1 in accordance with the first embodiments, an intermediate optical system 14 constituting an afocal system such that the intermediate optical system 14 is disposed at a location between a scanning optical system 12 and an exposure lens system 11. In an example shown in FIG. 6, a Keplerian afocal system constituted by two positive lenses 14a1 and 14a2 is illustrated as the intermediate optical system 14.

In the exposure device 1F, at a conjugate position of the above-described intersection position P with respect to the intermediate optical system 14, a new intersection position P′ of a light beam group entering the exposure lens system 11 is formed. Since the intermediate optical system 14 has positive power as a whole, the conjugate position of the above-described intersection position P is located on a rear side of the intermediate optical system 14. As a result, the new intersection position P′ is also formed at a location on the rear side of the intermediate optical system 14. The location of the intermediate optical system 14 is defined so that a distance D from the new intersection position P′ to a principal point of the exposure lens system 11 is equal to a front-side focal distance F1 of the exposure lens system 11.

In the exposure device 1F, a distance D from the intersection position P′ to the principal point of the exposure lens system 11 is equal to a front-side focal distance F1 of the exposure lens system 11 (a condition of telecentricity is satisfied). Therefore, similarly to the exposure device 1 in accordance with the first embodiments, the exposure device 1F can suppress or reduce distortion of a shape of an area where two-photon exposure occurs more than the conventional exposure device does, which distortion can occur at a location distant from an optical axis of the exposure lens system 11.

For the intermediate optical system 14, a positive lens 14a1 (condensing lens) on a front side is disposed such that a distance from the above-described intersection position P to a principal point of the positive lens 14a is equal to a front-side focal distance Fa1 of the positive lens 14a1. A positive lens 14a2 (imaging lens) on a rear side is disposed such that a distance from an intermediate light converging plane (intermediate imaging plane) to a principal point of the positive lens 14a2 is equal to a front-side focal distance Fa2 of the positive lens 14a2. As the positive lenses 14a1 and 14a2, two positive lenses in which the front-side focal distances Fa1 and Fa2 satisfy Fa1<Fa2 are employed. With this, the intermediate optical system 14 constitutes the Keplerian afocal system.

As described above, in the exposure device 1F, the intermediate optical system 14 constitutes the afocal system. Therefore, a diameter of a light beam entering the exposure lens system 11 is larger than a diameter of a light beam exiting from the scanning optical system 12.

Incidentally, in order to enhance exposure resolution of the exposure device 1 (e.g., at 0.5 um or more), it is necessary to increase a NA (numerical aperture) of the exposure lens system 11 (e.g., at 1.0 or more). Further, in order to sufficiently bring out the performance of the exposure lens system 11 having a large NA, it is necessary to increase a diameter of a light beam entering the exposure lens system 11 (e.g., at 18 mm or more). In a case where the intermediate optical system 14 is not present, it is necessary to increase a size of a mirror 12a constituting the scanning optical system 12, for the purpose of increasing the diameter of the light beam entering the exposure lens system 11. However, increasing the size of the mirror 12a constituting the scanning optical system 12 will result in increase in a weight of the mirror 12a and/or reduction in rigidity of the mirror 12a. This impairs high-speed scanning or precise scanning. On the other hand, in the exposure device 1F, the intermediate optical system 14 constitutes the afocal system. Therefore, it is possible to increase a diameter of a light beam entering the exposure lens system 11, even without increasing a size of the mirror 12a constituting the scanning optical system 12. Therefore, the exposure device 1F can enhance the exposure resolution of the exposure device 1, while making no sacrifice of high-speed scanning or precise scanning.

The following will describe, with reference to FIG. 7, a configuration of an exposure device 1G of one or more embodiments. FIG. 7 is a plan view of the exposure device 1G.

As shown in FIG. 7, the exposure device 1G is obtained by adding, to the exposure device 1 in accordance with the first embodiments, an intermediate optical system 14 constituting an afocal system such that the intermediate optical system 14 is disposed at a location between a scanning optical system 12 and an exposure lens system 11. In the example shown in FIG. 6, an optical system made of a combination of a Keplerian afocal system constituted by two positive lenses 14a1 and 14a2 and a Galilean afocal system constituted by one negative lens 14b1 and one positive lens 14a3 is shown as the intermediate optical system 14.

In the exposure device 1G, at a conjugate position of the above-described intersection position P with respect to the intermediate optical system 14, a new intersection position P′ of a light beam group entering the exposure lens system 11 is formed. Since the intermediate optical system 14 has positive power as a whole, the conjugate position of the above-described intersection position P is located on a rear side of the intermediate optical system 14. As a result, the new intersection position P′ is also formed at a location on the rear side of the intermediate optical system 14. The location of the intermediate optical system 14 is defined so that a distance D from the new intersection position P′ to a principal point of the exposure lens system 11 is equal to a front-side focal distance F1 of the exposure lens system 11.

In the exposure device 1G, a distance D from the intersection position P′ to the principal point of the exposure lens system 11 is equal to the front-side focal distance F1 of the exposure lens system 11 (a condition of telecentricity is satisfied). Therefore, similarly to the exposure device 1 in accordance with the first embodiments, the exposure device 1G can suppress or reduce distortion of a shape of an area where two-photon exposure occurs more than the conventional exposure device does, which distortion can occur at a location distant from an optical axis of the exposure lens system 11.

For the intermediate optical system 14, a positive lens 14a1 (condensing lens) disposed at a frontmost position is disposed such that a distance from the above-described intersection position P to a principal point of the positive lens 14al is equal to a front-side focal distance Fa1 of the positive lens 14a. The positive lens 14a2 (imaging lens) disposed at a second position from the front is disposed such that a distance from an intermediate light converging plane to the principal point of the positive lens 14a2 is equal to a front-side focal distance Fa2 of the positive lens 14a2. As the positive lenses 14a1 and 14a2, two positive lenses in which the front-side focal distances Fa1 and Fa2 satisfy Fa1<Fa2 are employed. With this, the combination of the positive lens 14a1 and the positive lens 14a2 constitutes the Keplerian afocal system.

A negative lens 14b disposed at a second position from the rear side is disposed such that a distance from the principal point of the positive lens 14a2 to a principal point of the negative lens 14b is equal to a difference Fa2′-Fb between a rear-side focal distance Fa2′ of the positive lens 14a2 and a front-side focal distance Fb of the negative lens 14b. A positive lens 14a3 disposed at a rearmost position is disposed such that a distance from a principal point of the positive lens 14a3 to the intersection position P′ is equal to a rear-side focal distance Fa3′ of the positive lens 14a3. As the negative lens 14b and the positive lens 14a3, a negative lens and a positive lens in which focal distances Fb and Fa3′ satisfy Fb<Fa3′ are employed. Thus, the combination of the negative lens 14b and the positive lens 14a3 constitutes the Galilean afocal system.

As described above, in the exposure device 1G, the intermediate optical system 14 constitutes the afocal system. Therefore, a diameter of a light beam entering the exposure lens system 11 is larger than a diameter of a light beam exiting from the scanning optical system 12. Therefore, similarly to the exposure device 1F, the exposure device 1G can enhance the exposure resolution of the exposure device 1, while making no sacrifice of high-speed scanning or precise scanning.

### Supplementary Remark

Similarly to the exposure device 1 in accordance with the first embodiments, the exposure devices 1F and 1G in accordance with the present embodiments may be configured such that the distance D from the intersection position P′ to the principal point of the exposure lens system 11 satisfies 0<D<2×F1 and is not limited to D=F1.

Further, similarly to the exposure devices 1A, 1B, and 1C in accordance with the second embodiments, the exposure devices 1F and 1G in accordance with the present embodiments may also be configured such that a front optical system 13 is disposed on a front side of the scanning optical system 12.

### Fifth Embodiments

The following description will discuss, with reference to FIGS. 8 and 9, fifth embodiments of the present invention. The first to fourth embodiments each employ the configuration in which two-dimensional scanning is carried out by the mirror 12a. Meanwhile, the present embodiments employ a configuration in which two-dimensional scanning is carried out by a mirror 12a and an optical switch 12c.

### Configuration of Exposure Device

The following will describe, with reference to FIG. 8, a configuration of an exposure device 1H of one or more embodiments. FIG. 8 is a plan view of the exposure device 1H, viewed in a y-axis direction and an x-axis direction.

As shown in FIG. 8, the exposure device 1H is configured such that, in the exposure device 1 in accordance with the first embodiments, a scanning optical system 12 is constituted by the mirror 12a, a lens 12b, the optical switch 12c, and a lens 12d. The mirror 12a is a mirror which is turnable around the y-axis and which serves to carry out one-dimensional scanning in the x-axis direction. The lens 12b is a cylindrical lens having positive power in a zx-plane. The optical switch 12c is a transmissive optical switch which includes a plurality of lines arranged in parallel with the x-axis and which is capable of switching a state of each of the lines between an open state where light is transmitted and a closed state where light is blocked. The optical switch 12c serves to carry out one-dimensional scanning in the y-axis direction. The optical switch 12c is disposed on an intermediate light converging plane where a light beam having passed through the lens 12b is condensed on the zx-plane. The lens 12d is a positive lens having positive power in the zx-plane and in a yz-plane.

In the exposure device 1H, at a location which is on a rear side of the scanning optical system 12, a new intersection position P of a light beam group entering the exposure lens system 11 is formed. In the exposure device 1H, a distance D from the intersection position P to a principal point of the exposure lens system 11 is equal to a front-side focal distance F1 of the exposure lens system 11 (a condition of telecentricity is satisfied). Therefore, similarly to the exposure device 1 in accordance with the first embodiments, the exposure device 1H can suppress or reduce distortion of a shape of an area where two-photon exposure occurs more than the conventional exposure device does, which distortion can occur at a location distant from an optical axis of the exposure lens system 11.

Furthermore, in the exposure device 1H, the mirror 12a, which serves to carry out one-dimensional scanning in the x-axis direction, and the optical switch 12c, which serves to carry out one-dimensional scanning in the y-axis direction, are combined to realize two-dimensional scanning. Thus, as compared to a case where two-dimensional scanning is realized only by using an optical switch (i.e., an optical switch which includes a plurality of cells arranged in a matrix and which is capable of switching a state of each of the cells between an open state and a closed state), the exposure device 1H can reduce a loss of light, and consequently can increase an energy density of a light-converged area.

Given that Δ denotes a cell size of the optical switch 12c and β denotes a magnification of an optical system constituted by the lens 12d and the exposure lens system 11, each of the light beams B11 and B12 in the light-converged areas A11 and A12 has a width of approximately βΔ in the y-axis direction. The width βΔ may be at a diffraction limit or less. For example, in a case where β<1, it is possible to set the width BA at the diffraction limit or less even when the cell size Δ of the optical switch 12c is at the diffraction limit or more.

Note that the optical switch 12c may be a reflective optical switch, such as a Digital Mirror Device (DMD). FIG. 9 illustrates an exposure device 1H including a reflective optical switch in place of the optical switch 12c. In the case where the optical switch 12c is of a reflective type, turning-back of a light beam at the optical switch 12c occurs. Except for this, the exposure device 1H including the reflective optical switch 12c is the same as the exposure device 1H including the transmissive optical switch 12c.

### Supplementary Remark

Similarly to the exposure device 1 in accordance with the first embodiments, the exposure device 1H in accordance with the present embodiments may be configured such that the distance D from the intersection position P to the principal point of the exposure lens system 11 satisfies 0<D<2×F1 and is not limited to D=F1.

Further, similarly to the exposure devices 1A, 1B, and 1C in accordance with the second embodiments, the exposure device 1H in accordance with the present embodiments may also be configured such that a front optical system 13 is disposed on a front side of the scanning optical system 12.

Furthermore, similarly to the exposure device 1F in accordance with the fourth embodiments, the exposure device 1H in accordance with the present embodiments may also be configured such that the lens 12b and the lens 12d constitute the afocal system.

### Examples

The following will describe, with reference to FIGS. 10 and 11, a result of checking, by numerical calculation, a shape of a light-converged area in the exposure device 1G shown in FIG. 7.

FIG. 10 is a plan view illustrating a configuration of the exposure device 1G for which the numerical calculation was carried out. (a) of FIG. 11 shows graphs showing distributions of intensities of light obtained when light-converged areas were formed by using the exposure device 1G, the light-converged areas being respectively formed at a location on the optical axis (y=0 mm) of the exposure lens system 11, at a location (y=0.225) away from the optical axis by 0.225 mm, at a location (y=0.315) away from the optical axis by 0.315 mm, and at a location (y=0.45 mm) away from the optical axis by 0.45 mm. (b) of FIG. 11 shows graphs showing distributions of intensities of light obtained from light-converged areas which were formed by using the conventional exposure device shown in FIG. 12, the light-converged areas being respectively formed at a location on an optical axis (y=0 mm) of an exposure lens system, at a location (y=0.225) away from the optical axis by 0.225 mm, at a location (y=0.315) away from the optical axis by 0.315 mm, and at a location (y=0.45 mm) away from the optical axis by 0.45 mm.

(b) of FIG. 11 shows that, in the case where the conventional exposure device was used, an inclination of a center axis (indicated by a white line) of a light-converged area with respect to the z-axis increased with increasing distance from the light-converged area to the optical axis of the exposure lens system. Meanwhile, (a) of FIG. 11 shows that, in the case where the exposure device 1G was used, a center axis (indicated by a white line) of a light-converged area was kept in parallel with the z-axis with increasing distance from the light-converged area to the optical axis of the exposure lens system. Thus, it was confirmed that, in the case where the exposure lens system 1G was used, distortion of a shape of an area where two-photon exposure occurs more than the conventional exposure device does, which distortion can occur at a location distant from the optical axis of the exposure lens system 11.

### Application Examples

In order to realize optical computation, an optical computing device constituted by at least one light modulation layer is employed. An optical computing device including a plurality of light modulation layers can be used as, for example, a diffusion deep neural network (which may also be called a “D2NN”). In such an optical computing device, each light modulation layer is constituted by a plurality of cells having respective refractive indices set independently of each other. The optical computing device having such a configuration is manufactured by, for example, carrying out dehydration shrinkage on a swollen gel into which a refractive index distribution is written. A gel used in the Implosion Fabrication process is dehydrated and shrunk while keeping similarity, and therefore may be used as a raw material of such an optical computing device.

In order to write the refractive index distribution into the swollen gel, the refractive indices of the respective cells in each light modulation layer needs be set at a desired value. Setting of the refractive indices as above can be realized by causing two-photon absorption in colorants contained in the swollen gel. This happens in the following manner. That is, when two-photon absorption is caused in colorants, a change occurs in refractive indices in a portion of a gel base material which portion is around the colorants. The above-described exposure devices 1A to 1H may be used for two-photon exposure for causing such two-photon absorption. In this case, the above-described sample T is a swollen gel.

With each of the exposure devices 1,1A to 1H, it is possible to carry out highly-precise writing of the refractive index distribution even at a location distant from the optical axis of the exposure lens system 11. In particular, with each of the exposure devices 1A to 1G having a focus adjustment function, it is possible to carry out, in each of the plurality of light modulation layers, highly-precise writing of the refractive index distribution even at a location distant from the optical axis of the exposure lens system 11.

FIG. 12 shows one example of an optical computing device 100 produced in the above-described manner. The optical computing device 100 includes a dry gel 101. The dry gel 101 includes n (n is an integer of not less than 2; in the illustrated example, n=3) light diffraction layers Li (i is an integer of 1≤i≤n). In an example shown in FIG. 13, a light diffraction layer L1, a light diffraction layer L2, and a light diffraction layer L3 are stacked in this order.

Each light diffraction layer Li includes a plurality of microcells Cijk arranged in a matrix constituted by 1 rows and m columns (each of 1 and m is an integer of not less than 2; in the illustrated example, 1=m=4). Here, j is an integer of 1≤j≤1, and k is an integer of 1≤k≤m. The microcells Cijk have respective refractive indexes set individually and independently of each other. Further, in addition to the refractive indices, the microcells Cijk may respective refractive thicknesses Tc set individually and independently of each other.

It should be noted that the term “microcell” refers to, for example, a cell having a cell size of less than 10 μm. The term “cell size” refers to a square root of an area of a cell. For example, in a case where a microcell has a square shape in a plan view like the microcell Cijk, the cell size is a length Lc of one side of the cell. A lower limit of the cell size is not particularly limited, and is 1 nm, for example.

An interlayer pitch PL and the length Lc, which is the cell size of the microcell Cijk, are set in association with a wavelength as of signal light. The interlayer pitch PL may be an integer multiple of the wavelength as of the signal light. The interlayer pitch PL herein is 40 λs. For example, in a case where signal light of λs=400 nm is employed, PL=16 μm. The length Lc, which is the cell size of the microcell Cijk, may be set within a range of not less than λs/2 and not more than 2λs. For example, in a case where signal light of λs=400 nm is employed, the length Lc may be set within a range of not less than 200 nm and not more than 800 nm.

Aspects of the present invention can also be expressed as follows:

An exposure device in accordance with a first aspect of the present invention includes: an exposure lens system which has positive power; and a scanning optical system which is configured to switch, from one to another, a direction of a principal ray of a light beam entering the exposure lens system, a distance D satisfying 0<D<2×F1, where the distance D is a distance from (a) a single intersection position of a light beam group entering the exposure lens system or, among a plurality of intersection positions of the light beam group, an intersection position closest to the exposure lens system to (b) a principal point of the exposure lens system and F1 denotes a front-side focal distance of the exposure lens system.

With the above configuration, a shape of an area where a given exposure phenomenon occurs can be made more closely resemble a desired shape even at a location distant from an optical axis of the exposure lens system.

An exposure device in accordance with a second aspect employs, in addition to the configuration of the exposure device in accordance with the first aspect, a configuration in which the distance D satisfies 0<D≤F1.

The above configuration can reduce the size of the device more and can reduce the effect of disturbance on exposure resolution more, as compared to the configuration in which F1<D<2×F1 is satisfied.

An exposure device in accordance with a third aspect employs, in addition to the configuration of the exposure device in accordance with the first aspect, a configuration in which the distance D satisfies F1≤D<2×F1.

The above configuration can increase the scanning speed more and can correct distortion more easily, as compared to the configuration in which 0<D<F1 is satisfied.

An exposure device in accordance with a fourth aspect employs, in addition to the configuration of the exposure device in accordance with the first aspect, a configuration in which the distance D is equal to the front-side focal distance F1′.

With the above configuration, a shape of an area where a given exposure phenomenon occurs can be made far more closely resemble a desired shape even at a location distant from the optical axis of the exposure lens system.

An exposure device in accordance with a fifth aspect employs, in addition to the configuration of the exposure device in accordance with any one of the first to fourth aspects, a configuration in which the exposure device further includes: a front optical system disposed at a location which is on a front side of the scanning optical system, the front optical system having positive power or negative power.

With the above configuration, the light-converged area can be made closer to or more distant from the exposure lens system by making the front optical system closer to or more distant from the scanning optical system.

An exposure device in accordance with a sixth aspect employs, in addition to the configuration of the exposure device in accordance with any one of the first to fifth aspects, a configuration in which the exposure device further includes: an intermediate optical system disposed at a location which is on a rear side of the scanning optical system and on a front side of the exposure lens system, the intermediate optical system having positive power or negative power.

With the above configuration, the light-converged area can be made closer to or more distant from the exposure lens system by making the intermediate optical system closer to or more distant from the exposure lens system.

An exposure device in accordance with a seventh aspect employs, in addition to the configuration of the exposure device in accordance with any one of the first to fifth aspects, a configuration in which the exposure device further includes: an intermediate optical system disposed at a location which is on a rear side of the scanning optical system and on a front side of the exposure lens system, the intermediate optical system constituting an afocal system.

With the above configuration, a shape of an area where a given exposure phenomenon occurs can be made more closely resemble a desired shape even at a location distant from the optical axis of the exposure lens system, while making no sacrifice of high-speed scanning or precise scanning.

An exposure device in accordance with an eighth aspect employs, in addition to the configuration of the exposure device in accordance with the seventh aspect, a configuration in which the intermediate optical system includes a Keplerian afocal system.

With the above configuration, a shape of an area where a given exposure phenomenon occurs can be made far more closely resemble a desired shape even at a location distant from the optical axis of the exposure lens system, while making no sacrifice of high-speed scanning or precise scanning.

An exposure device in accordance with a ninth aspect employs, in addition to the configuration of the exposure device in accordance with the seventh or eighth aspect, a configuration in which the intermediate optical system includes a Galilean afocal system.

With the above configuration, a shape of an area where a given exposure phenomenon occurs can be made far more closely resemble a desired shape even at a location distant from the optical axis of the exposure lens system, while making no sacrifice of high-speed scanning or precise scanning.

An exposure device in accordance with a tenth aspect employs, in addition to the configuration of the exposure device in accordance with any one of the first to ninth aspects, a configuration in which the scanning optical system includes a mirror for carrying out one-dimensional scanning of a light beam entering the exposure lens system, the one-dimensional scanning being carried out in a direction which is in parallel with a first axis and an optical switch for carrying out one-dimensional scanning of a light beam entering the exposure lens system, the one-dimensional scanning being carried out in a direction which is in parallel with a second axis intersecting the first axis.

With the above configuration, two-dimensional scanning is realized by the mirror serving to carry out one-dimensional scanning in the direction which is in parallel with the first axis and the optical switch serving to carry out one-dimensional scanning in the direction which is in parallel with the second axis. Thus, as compared to a case where two-dimensional scanning is realized only by using an optical switch (i.e., an optical switch which includes a plurality of cells arranged in a matrix and which is capable of switching a state of each of the cells between an open state and a closed state), the above configuration can reduce a loss of light, and consequently can increase an energy density of a light-converged area.

An exposure method in accordance with an eleventh aspect is an exposure method including: carrying out two-photon exposure by using an exposure device recited in any one of the first to tenth aspects.

With the above configuration, a shape of an area where two-photon absorption occurs can be made more closely resemble a desired shape even at a location distant from the optical axis of the exposure lens system.

A method, in accordance with a twelfth aspect, for producing an optical computing device is a method for producing an optical computing device including the step of: writing a refractive index distribution into a light modulation layer by using an exposure method recited in the eleventh aspect.

With the above configuration, it is possible to produce an optical computing device including a light modulation layer constituted by cells having no distortion.

### Supplementary Note

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1, 1A to 1G: exposure device
11: exposure lens system
12: scanning optical system
13: front optical system
14: intermediate optical system
15: optical switch

1. An exposure device comprising:
an exposure lens system having positive power; and
a scanning optical system configured to switch a direction of a principal ray of a light beam entering the exposure lens system, wherein
0<D<2×F1, where
D is a distance from a principal point of the exposure lens system to either of:
an intersection position of a light beam group entering the exposure lens system, or
among intersection positions of a light beam group entering the exposure lens system, an intersection position closest to the exposure lens system, and
F1 is a front-side focal distance of the exposure lens system.

2. The exposure device according to claim 1, wherein 0<D≤F1.

3. The exposure device according to claim 1, wherein F1≤D<2×F1.

4. The exposure device according to claim 1, wherein D=F1.

5. The exposure device according to claim 1, further comprising a front optical system having positive power or negative power at a location on a front side of the scanning optical system.

6. The exposure device according to claim 1, further comprising an intermediate optical system having positive power or negative power at a location on a rear side of the scanning optical system and on a front side of the exposure lens system.

7. The exposure device according to claim 1, further comprising an intermediate optical system constituting an afocal system at a location on a rear side of the scanning optical system and on a front side of the exposure lens system.

8. The exposure device according to claim 7, wherein the intermediate optical system comprises a Keplerian afocal system.

9. The exposure device according to claim 7, wherein the intermediate optical system comprises a Galilean afocal system.

10. The exposure device according to claim 1, wherein
the scanning optical system comprises:
a mirror configured to carry out one-dimensional scanning of the light beam in a direction parallel with a first axis; and
an optical switch configured to carry out one-dimensional scanning of the light beam in a direction parallel with a second axis intersecting the first axis.

11. An exposure method comprising carrying out two-photon exposure using an exposure device recited in claim 1.

12. A method for producing an optical computing device, comprising writing a refractive index distribution into a light modulation layer using an exposure method recited in claim 11.
